(19) United States
(12) Patent Application Publication
(10) Pub. No.: US 2026/0004833 A1
(43) Pub. Date: Jan. 1, 2026

(54) APPARATUS AND METHODS FOR AMPLIFIER CIRCUITS FOR READING MRAM MEMORY CELLS

(71) Applicant: Sandisk Technologies, Inc., Milpitas, CA (US)

(72) Inventors: Nicolas Irizarry, Folsom, CA (US); Ashraf B. Islam, El Dorado Hills, CA (US); Jaydip Patel, Folsom, CA (US); Christopher J. Petti, Folsom, CA (US)

(73) Assignee: Sandisk Technologies, Inc., Milpitas, CA (US)

(21) Appl. No.: 18/756,731

(22) Filed: Jun. 27, 2024

(51) Int. Cl. G11C 11/16

(52) U.S. Cl. CPC G11C 11/1673; G11C 11/161; G11C 11/1657; G11C 11/1659; G11C 11/1697

(57) ABSTRACT

An apparatus includes a memory cell including a magnetic memory element coupled in series with a selector element, the memory cell including a first terminal coupled to a word line driver circuit and a second terminal coupled to a bit line driver circuit, and an amplifier circuit comprising an input terminal coupled to the bit line driver circuit, and an output terminal coupled to a current source configured to conduct a read current. The amplifier circuit is configured to amplify a voltage that is based on a difference between a first voltage across the memory cell and a second voltage across the memory cell.

### BACKGROUND

Memory is widely used in various electronic devices such as cellular telephones, digital cameras, personal digital assistants, medical electronics, mobile computing devices, non-mobile computing devices and data servers. Memory may be non-volatile memory or volatile memory. A non-volatile memory allows information to be stored and retained even when the non-volatile memory is not connected to a source of power (e.g., a battery).

One example of a non-volatile memory is magnetoresistive random access memory (MRAM), which uses magnetization to represent stored data, in contrast to some other memory technologies that store data using electronic charge. Generally, MRAM includes a large number of magnetic memory cells formed on a semiconductor substrate, where each memory cell represents one bit of data.

A data bit is written to a memory cell by changing the direction of magnetization of a magnetic element within the memory cell, and a bit is read by measuring the resistance of the memory cell (low resistance typically represents a “0” bit, and high resistance typically represents a “1” bit). As used herein, direction of magnetization is the direction of orientation of the magnetic moment. Some memory cells may include a selector device, such as an ovonic threshold switch or other selector device.

Although MRAM is a promising technology, numerous design and process challenges remain.

### BRIEF DESCRIPTION OF THE DRAWINGS

FIGS. 1A-1H depict various embodiments of a memory system.

FIG. 2A depicts an embodiment of a portion of a three-dimensional memory array.

FIG. 2B depicts an embodiment of a memory cell of the three-dimensional memory array of FIG. 2A.

FIG. 2C depicts an example current-voltage characteristic of a threshold selector device of FIG. 2B.

FIGS. 3A-3B depict an embodiment of a cross-point memory array.

FIG. 4 is a simplified diagram of an example memory circuit during a read operation of a memory cell.

FIG. 5 is a simplified diagram of another example memory circuit during a read operation of a memory cell.

FIG. 6 depicts a flow diagram of an embodiment of a method for configuring a memory cell, such as the example memory cell of FIG. 2B.

### DETAILED DESCRIPTION

One type of memory array includes multiple word lines, multiple bit lines, and MRAM memory cells that include a magnetic memory element coupled in series with a selector element disposed at the intersections of each word line and each bit line.

A challenge with MRAM technologies is sensing a difference between a low resistance and high resistance states of MRAM memory cells. One read technique involves conducting a current through the MRAM memory cell, and then measuring a voltage drop across the memory cell.

An MRAM memory cell will have a first voltage drop in a low resistance state, and will have a second (larger) voltage drop in a high resistance state. In some MRAM technologies, a difference between the first voltage drop and the second voltage drop is about 200 mV.

However, this signal may become attenuated traveling from the middle of a memory array to a sense amplifier circuit used to detect the voltages. For example, what starts as a 200 mV difference may reduce to about a 50 mV difference at an input to the sense amplifier circuit. Such a small voltage difference is difficult to distinguish in actual sense amplifier circuits, which may have offset voltages as a result of device mismatches.

Technology is described to amplify the signal to increase the voltage difference at the input to the sense amplifier circuit. In an embodiment, a common-gate amplifier circuit is inserted between the bit line coupled to the memory cell and the sense amplifier circuit. In an embodiment, the common gate amplifier is a p-channel transistor,

In embodiments, the memory cells include a memory element coupled in series with a selector device. In an embodiment, the memory element is a magnetic memory element. In an embodiment, the memory element is a magnetic tunnel junction memory element. In an embodiment, the selector device is an ovonic threshold switch.

In an embodiment, memory cells within a memory array may include non-volatile memory cells including a reversible resistance-switching element. A reversible resistance-switching element may include a reversible resistivity-switching material having a resistivity that may be reversibly switched between two or more states.

In an embodiment, the reversible resistance-switching material may include a metal oxide, solid electrolyte, phase-change material, magnetic material, or other similar resistivity-switching material. Various metal oxides can be used, such as transition metal-oxides. Examples of metal-oxides include, but are not limited to, NiO, Nb₂O₅, TiO₂, HfO₂, Al₂O₃, MgOₓ, CrO₂, VO, BN, TaO₂, Ta₂O₃, and AlN.

In an embodiment, non-volatile memory cells within a memory array include one-time programmable memory cells. In an embodiment, non-volatile memory cells within a memory array include re-writeable memory cells.

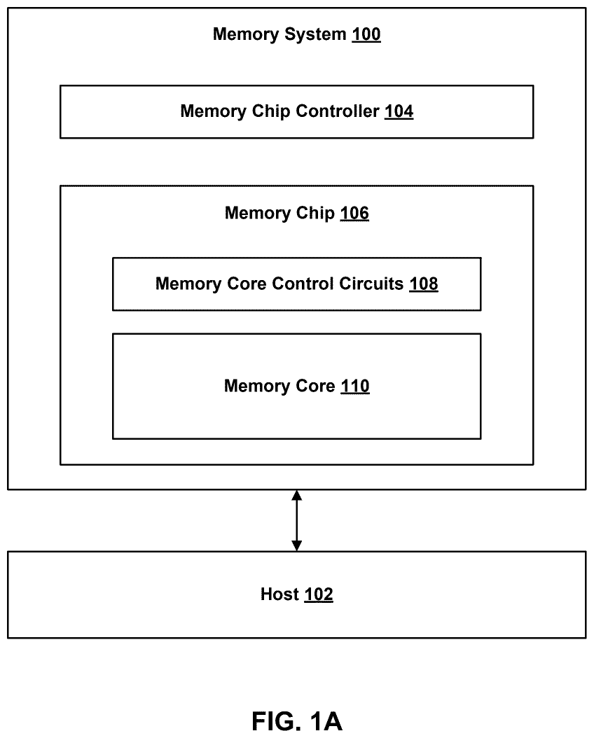

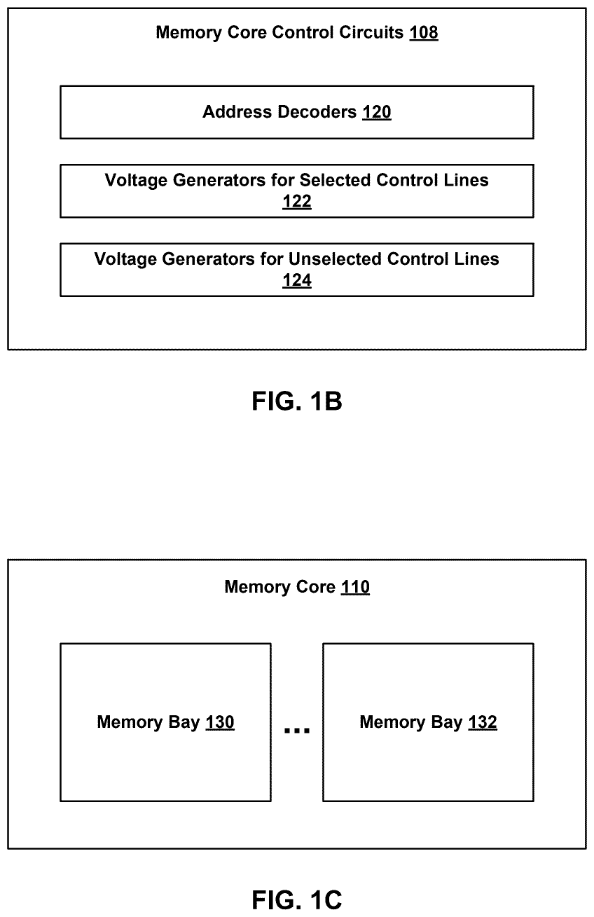

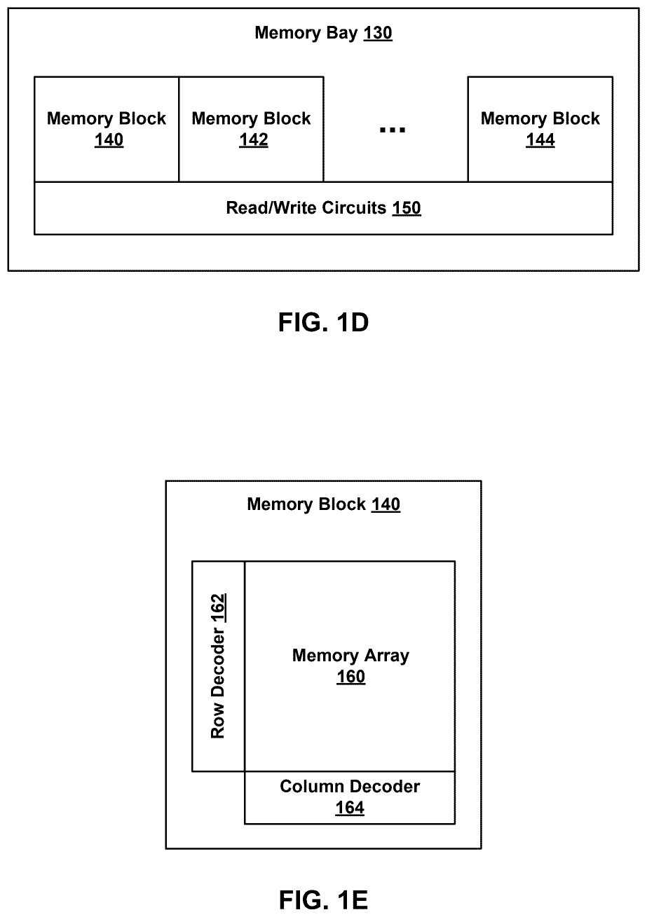

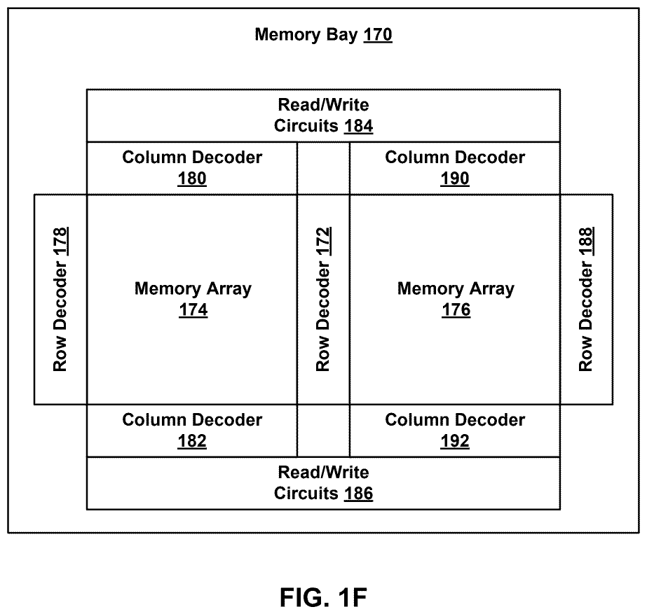

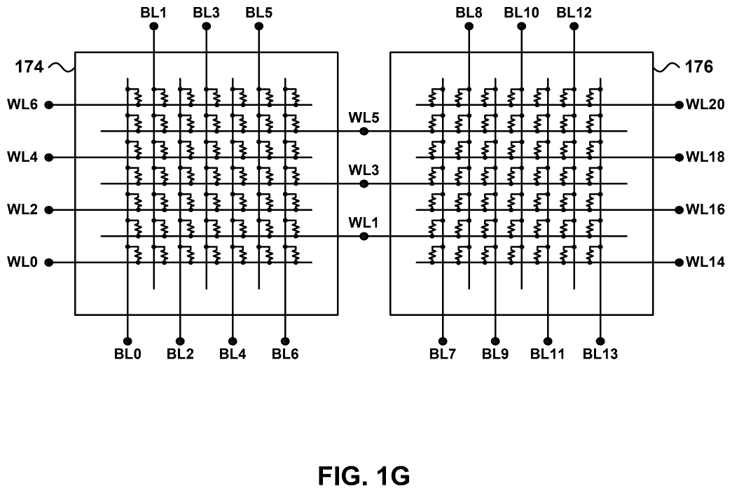

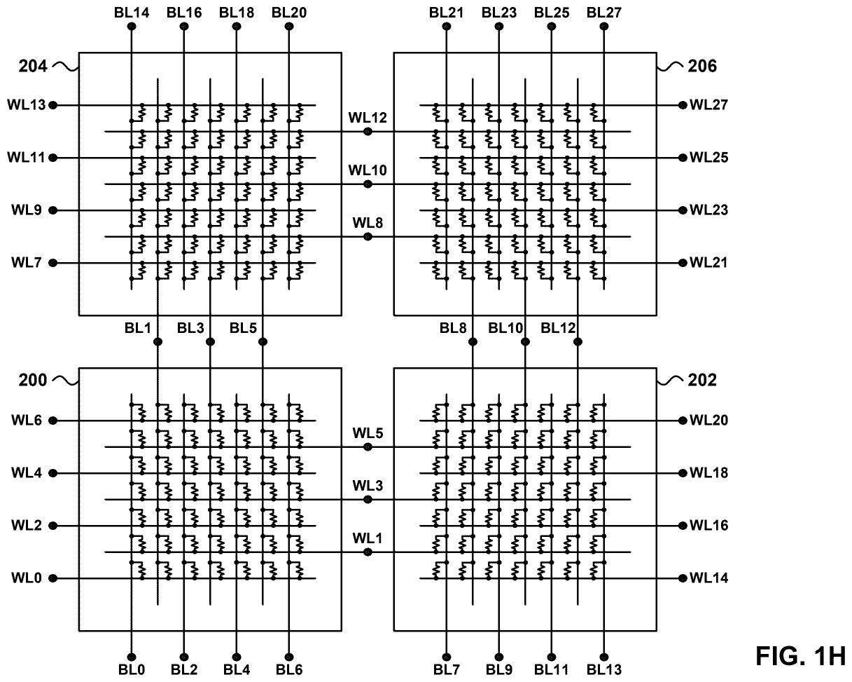

FIG. 1A depicts one embodiment of a memory system 100 and a host 102. Memory system 100 may include a non-volatile storage system interfacing with host 102 (e.g., a mobile computing device or a server). In some cases, memory system 100 may be embedded within host 102. As examples, memory system 100 may be a memory card, a solid-state drive (SSD) such a high density MLC SSD (e.g., 2-bits/cell or 3-bits/cell) or a high performance SLC SSD, or a hybrid HDD/SSD drive.

As depicted, memory system 100 includes a memory chip controller 104 and a memory chip 106. Memory chip 106 may include volatile memory and/or non-volatile memory. Although a single memory chip is depicted, memory system 100 may include more than one memory chip. Memory chip controller 104 may receive data and commands from host 102 and provide memory chip data to host 102.

Memory chip controller 104 may include one or more of control circuitry, state machines, page registers, SRAM, decoders, sense amplifiers, read/write circuits, and/or controllers, or any combination thereof, for controlling the operation of memory chip 106. The one or more control circuitry, state machines, page registers, SRAM, decoders, sense amplifiers, read/write circuits, and/or controllers for controlling the operation of the memory chip may be referred to as managing or control circuits. The managing or control circuits may facilitate one or more memory array operations including forming, erasing, programming, or reading operations.

In some embodiments, the managing or control circuits (or a portion of the managing or control circuits) for facilitating one or more memory array operations may be integrated within memory chip 106. Memory chip controller 104 and memory chip 106 may be arranged on a single integrated circuit or arranged on a single die. In other embodiments, memory chip controller 104 and memory chip 106 may be arranged on different integrated circuits. In some cases, memory chip controller 104 and memory chip 106 may be integrated on a system board, logic board, or a PCB.

Memory chip 106 includes memory core control circuits 108 and a memory core 110. Memory core control circuits 108 may include logic for controlling the selection of memory blocks (or arrays) within memory core 110, controlling the generation of voltage references for biasing a particular memory array into a read or write state, and generating row and column addresses.

Memory core 110 may include one or more two-dimensional arrays of memory cells and/or one or more three-dimensional arrays of memory cells. In an embodiment, memory core may include re-writable memory cells, one-time programmable memory cells, and/or multi-time programmable memory cells, or any combination thereof.

In an embodiment, memory core control circuits 108 and memory core 110 may be arranged on a single integrated circuit. In other embodiments, memory core control circuits 108 (or a portion of memory core control circuits 108) and memory core 110 may be arranged on different integrated circuits.

A memory operation may be initiated when host 102 sends instructions to memory chip controller 104 indicating that host 102 would like to read data from memory system 100 or write data to memory system 100. In the event of a write (or programming) operation, host 102 may send to memory chip controller 104 both a write command and the data to be written.

Memory chip controller 104 may buffer data to be written and may generate error correction code (ECC) data corresponding with the data to be written. The ECC data, which allows data errors that occur during transmission or storage to be detected and/or corrected, may be written to memory core 110 or stored in non-volatile memory within memory chip controller 104. In an embodiment, the ECC data are generated and data errors are corrected by circuitry within memory chip controller 104.

Memory chip controller 104 may control operation of memory chip 106. In an example, before issuing a write operation to memory chip 106, memory chip controller 104 may check a status register to make sure that memory chip 106 is able to accept the data to be written.

In another example, before issuing a read operation to memory chip 106, memory chip controller 104 may pre-read overhead information associated with the data to be read. The overhead information may include ECC data associated with the data to be read or a redirection pointer to a new memory location within memory chip 106 in which to read the data requested.

Once memory chip controller 104 initiates a read or write operation, memory core control circuits 108 may generate appropriate bias voltages and/or currents for word lines and bit lines within memory core 110, as well as generate the appropriate memory block, row, and column addresses.

FIG. 1B depicts an embodiment of memory core control circuits 108. In an embodiment, memory core control circuits 108 include address decoders 120, voltage generators for selected control lines 122, and voltage generators for unselected control lines 124. Control lines may include word lines, bit lines, or a combination of word lines and bit lines. Selected control lines may include selected word lines or selected bit lines that are used to place memory cells into a selected state. Unselected control lines may include unselected word lines or unselected bit lines that are used to place memory cells into an unselected state.

Voltage generators (or voltage regulators) for selected control lines 122 may include one or more voltage generators for generating selected control line voltages. Voltage generators for unselected control lines 124 may include one or more voltage generators for generating unselected control line voltages. Address decoders 120 may generate memory block addresses, as well as row addresses and column addresses for a particular memory block.

FIGS. 1C-1F depict one embodiment of a memory core organization that includes a memory core 110 having multiple memory bays, and each memory bay having multiple memory blocks. Although a memory core organization is disclosed where memory bays include memory blocks, and memory blocks include a group of memory cells, other organizations or groupings also can be used with the technology described herein.

FIG. 1C depicts an embodiment of memory core 110 of FIG. 1A. As depicted, memory core 110 includes memory bay 130 and memory bay 132. In some embodiments, the number of memory bays per memory core can be different for different implementations. For example, a memory core may include only a single memory bay or multiple memory bays (e.g., 16 memory bays, 256 memory bays, etc.).

FIG. 1D depicts one embodiment of memory bay 130 of FIG. 1C. As depicted, memory bay 130 includes memory blocks 140-144 and read/write circuits 150. In some embodiments, the number of memory blocks per memory bay may be different for different implementations. For example, a memory bay may include one or more memory blocks (e.g., 32 memory blocks per memory bay).

Read/write circuits 150 include circuitry for reading and writing memory cells within memory blocks 140-144. As depicted, read/write circuits 150 may be shared across multiple memory blocks within a memory bay. This allows chip area to be reduced because a single group of read/write circuits 150 may be used to support multiple memory blocks. However, in some embodiments, only a single memory block may be electrically coupled to read/write circuits 150 at a particular time to avoid signal conflicts.

In some embodiments, read/write circuits 150 may be used to write one or more pages of data into memory blocks 140-144 (or into a subset of the memory blocks). The memory cells within memory blocks 140-144 may permit direct over-writing of pages (i.e., data representing a page or a portion of a page may be written into memory blocks 140-144 without requiring an erase or reset operation to be performed on the memory cells prior to writing the data).

In an example, memory system 100 of FIG. 1A may receive a write command including a target address and a set of data to be written to the target address. Memory system 100 may perform a read-before-write (RBW) operation to read the data currently stored at the target address before performing a write operation to write the set of data to the target address. Memory system 100 may then determine whether a particular memory cell may stay at its current state (i.e., the memory cell is already at the correct state), needs to be set to a “0” state, or needs to be reset to a “1” state.

Memory system 100 may then write a first subset of the memory cells to the “0” state and then write a second subset of the memory cells to the “1” state. The memory cells that are already at the correct state may be skipped over, thereby improving programming speed and reducing the cumulative voltage stress applied to unselected memory cells.

A particular memory cell may be set to the “1” state by applying a first voltage difference across the particular memory cell of a first polarity (e.g., +1.5V). The particular memory cell may be reset to the “0” state by applying a second voltage difference across the particular memory cell of a second polarity that is opposite to that of the first polarity (e.g., −1.5V).

In some cases, read/write circuits 150 may be used to program a particular memory cell to be in one of three or more data/resistance states (i.e., the particular memory cell may comprise a multi-level memory cell). In an example, read/write circuits 150 may apply a first voltage difference (e.g., 2V) across the particular memory cell to program the particular memory cell to a first state of the three or more data/resistance states, or a second voltage difference (e.g., 1V) across the particular memory cell that is less than the first voltage difference to program the particular memory cell to a second state of the three or more data/resistance states.

Applying a smaller voltage difference across the particular memory cell may cause the particular memory cell to be partially programmed or programmed at a slower rate than when applying a larger voltage difference. In another example, read/write circuits 150 may apply a first voltage difference across the particular memory cell for a first time period (e.g., 150 ns) to program the particular memory cell to a first state of the three or more data/resistance states, or apply the first voltage difference across the particular memory cell for a second time period less than the first time period (e.g., 50 ns). One or more programming pulses followed by a memory cell verification phase may be used to program the particular memory cell to be in the correct state.

FIG. 1E depicts one embodiment of memory block 140 of FIG. 1D. As depicted, memory block 140 includes a memory array 160, a row decoder 162, and a column decoder 164. Memory array 160 may include a contiguous group of memory cells having contiguous word lines and bit lines. Memory array 160 may include one or more layers of memory cells, and may include a two-dimensional memory array and/or a three-dimensional memory array.

Row decoder 162 decodes a row address and selects a particular word line in memory array 160 when appropriate (e.g., when reading or writing memory cells in memory array 160). Column decoder 164 decodes a column address and selects a particular group of bit lines in memory array 160 to be electrically coupled to read/write circuits, such as read/write circuits 150 of FIG. 1D. In an embodiment, the number of word lines is 4K per memory layer, the number of bit lines is 1K per memory layer, and the number of memory layers is 4, providing a memory array 160 containing 16M memory cells. Other numbers of word lines per layer, bit lines per layer, and number of layers may be used.

FIG. 1F depicts an embodiment of a memory bay 170. Memory bay 170 is an example of an alternative implementation for memory bay 130 of FIG. 1D. In some embodiments, row decoders, column decoders, and read/write circuits may be split or shared between memory arrays. As depicted, row decoder 172 is shared between memory arrays 174 and 176, because row decoder 172 controls word lines in both memory arrays 174 and 176 (i.e., the word lines driven by row decoder 172 are shared).

Row decoders 178 and 172 may be split such that even word lines in memory array 174 are driven by row decoder 178 and odd word lines in memory array 174 are driven by row decoder 172. Column decoders 180 and 182 may be split such that even bit lines in memory array 174 are controlled by column decoder 182 and odd bit lines in memory array 174 are driven by column decoder 180.

The selected bit lines controlled by column decoder 180 may be electrically coupled to read/write circuits 184. The selected bit lines controlled by column decoder 182 may be electrically coupled to read/write circuits 186. Splitting the read/write circuits into read/write circuits 184 and 186 when the column decoders are split may allow for a more efficient layout of the memory bay.

Row decoders 188 and 172 may be split such that even word lines in memory array 176 are driven by row decoder 188 and odd word lines in memory array 176 are driven by row decoder 172. Column decoders 190 and 192 may be split such that even bit lines in memory array 176 are controlled by column decoder 192 and odd bit lines in memory array 176 are driven by column decoder 190.

The selected bit lines controlled by column decoder 190 may be electrically coupled to read/write circuits 184. The selected bit lines controlled by column decoder 192 may be electrically coupled to read/write circuits 186. Splitting the read/write circuits into read/write circuits 184 and 186 when the column decoders are split may allow for a more efficient layout of the memory bay.

FIG. 1G depicts an embodiment of a schematic diagram (including word lines and bit lines) corresponding with memory bay 170 in FIG. 1F. As depicted, word lines WL1, WL3, and WL5 are shared between memory arrays 174 and 176 and controlled by row decoder 172 of FIG. 1F. Word lines WL0, WL2, WL4, and WL6 are driven from the left side of memory array 174 and controlled by row decoder 178 of FIG. 1F. Word lines WL14, WL16, WL18, and WL20 are driven from the right side of memory array 176 and controlled by row decoder 188 of FIG. 1F.

Bit lines BL0, BL2, BL4, and BL6 are driven from the bottom of memory array 174 and controlled by column decoder 182 of FIG. 1F. Bit lines BL1, BL3, and BL5 are driven from the top of memory array 174 and controlled by column decoder 180 of FIG. 1F. Bit lines BL7, BL9, BL11, and BL13 are driven from the bottom of memory array 176 and controlled by column decoder 192 of FIG. 1F. Bit lines BL8, BL10, and BL12 are driven from the top of memory array 176 and controlled by column decoder 190 of FIG. 1F.

In an embodiment, memory arrays 174 and 176 may include memory layers that are oriented in a plane that is horizontal to the supporting substrate. In another embodiment, memory arrays 174 and 176 may include memory layers that are oriented in a plane that is vertical with respect to the supporting substrate (i.e., the vertical plane is substantially perpendicular to the supporting substrate). In this case, the bit lines of the memory arrays may include substantially vertical bit lines.

FIG. 1H depicts one embodiment of a schematic diagram (including word lines and bit lines) corresponding with a memory bay arrangement wherein word lines and bit lines are shared across memory blocks, and both row decoders and column decoders are split. Sharing word lines and/or bit lines helps to reduce layout area because a single row decoder and/or column decoder can be used to support two memory arrays.

As depicted, word lines WL1, WL3, and WL5 are shared between memory arrays 200 and 202. Bit lines BL1, BL3, and BL5 are shared between memory arrays 200 and 204. Word lines WL8, WL10, and WL12 are shared between memory arrays 204 and 206. Bit lines BL8, BL10, and BL12 are shared between memory arrays 202 and 206.

Row decoders are split such that word lines WL0, WL2, WL4, and WL6 are driven from the left side of memory array 200 and word lines WL1, WL3, and WL5 are driven from the right side of memory array 200. Likewise, word lines WL7, WL9, WL11, and WL13 are driven from the left side of memory array 204 and word lines WL8, WL10, and WL12 are driven from the right side of memory array 204.

Column decoders are split such that bit lines BL0, BL2, BL4, and BL6 are driven from the bottom of memory array 200 and bit lines BL1, BL3, and BL5 are driven from the top of memory array 200. Likewise, bit lines BL7, BL9, BL11, and BL13 are driven from the bottom of memory array 202 and bit lines BL8, BL10, and BL12 are driven from the top of memory array 202. Splitting row and/or column decoders also helps to relieve layout constraints (e.g., the column decoder pitch can be relieved by 2x since the split column decoders need only drive every other bit line instead of every bit line).

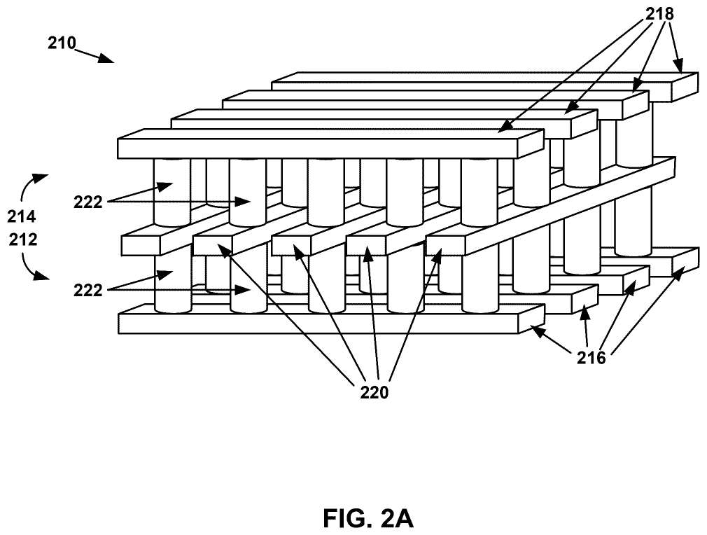

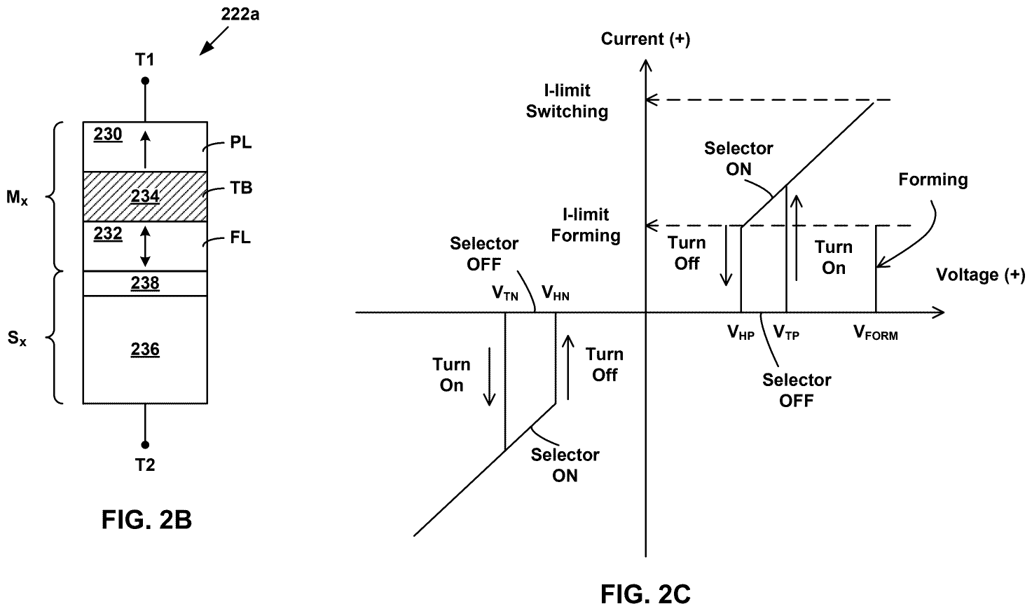

FIG. 2A depicts an embodiment of a portion of a monolithic three-dimensional memory array 210 that includes a first memory level 212, and a second memory level 214 positioned above first memory level 212. Memory array 210 is an example of an implementation of memory array 160 in FIG. 1E. Word lines 216 and 218 are arranged in a first direction and bit lines 220 are arranged in a second direction perpendicular to the first direction. As depicted, the upper conductors of first memory level 212 may be used as the lower conductors of second memory level 214. In a memory array with additional layers of memory cells, there would be corresponding additional layers of bit lines and word lines.

Memory array 210 includes memory cells 222. In embodiments, memory cells 222 may include re-writeable memory cells, one-time programmable memory cells, and multi-time programmable memory cells. In an embodiment, each of memory cells 222 are vertically-oriented. Memory cells 222 may include non-volatile memory cells or volatile memory cells. With respect to first memory level 212, a first portion of memory cells 222 are between and connect to word lines 216 and bit lines 220. With respect to second memory level 214, a second portion of memory cells 222 are between and connect to word lines 218 and bit lines 220.

In an embodiment, each memory cell 222 includes a selector element coupled in series with a resistance-switching memory element, where each memory cell 222 represents one bit of data. In an embodiment, the resistance-switching memory element may be a magnetic memory element, a ReRAM memory element, a phase change memory element or other type of resistance-switching memory element.

In an embodiment, each memory cell 222 includes a selector element coupled in series with a magnetic memory element, where each memory cell 222 represents one bit of data. FIG. 2B is a simplified schematic diagram of a memory cell 222a, which is one example implementation of memory cells 222 of FIG. 2A.

In an embodiment, memory cell 222a includes a magnetic memory element Mₓ coupled in series with a selector element Sₓ, both coupled between a first terminal T1 and a second terminal T2. In an embodiment, memory cell 222a is vertically-oriented. In the embodiment of FIG. 2B, magnetic memory element Mₓ is disposed above selector element Sₓ. In other embodiments, selector element Sₓ may be disposed above magnetic memory element Mₓ.

In an embodiment, magnetic memory element Mₓ is a magnetic tunnel junction, and selector element Sₓ is a threshold selector device. In an embodiment, selector element Sₓ is a conductive bridge threshold selector device. In other embodiments, selector element Sₓ is an ovonic threshold switch (e.g., binary SiTe, CTe, BTe, AlTe, etc., or the ternary type AsTeSi, AsTeGe or AsTeGeSiN, etc.), a Metal Insulator Transition (MIT) of a Phase Transition Material type (e.g., VO₂, NbO₂ etc.), or other similar threshold selector device.

In an embodiment, magnetic memory element Mₓ includes an upper ferromagnetic layer 230, a lower ferromagnetic layer 232, and a tunnel barrier (TB) 234 which is an insulating layer between the two ferromagnetic layers. In this example, lower ferromagnetic layer 232 is a free layer (FL) that has a direction of magnetization that can be switched. Upper ferromagnetic layer 230 is the pinned (or fixed) layer (PL) that has a direction of magnetization that is not easily changed.

In other embodiments, magnetic memory element Mₓ may include fewer, additional, or different layers than those depicted in FIG. 2B. In other embodiments, lower ferromagnetic layer 232 is a pinned layer (PL) and upper ferromagnetic layer 230 is the free layer (FL).

When the direction of magnetization in free layer 232 is parallel to that of pinned layer 230, memory element Mₓ has a relatively low resistance (referred to herein as the “P state”), and when the direction of magnetization in free layer 232 is anti-parallel to that of pinned layer 230, memory element Mₓ has a relatively high resistance (referred to herein as the “AP state”).

In an embodiment, the data state (“0” or “1”) of magnetic memory element Mₓ is read by measuring the resistance of magnetic memory element Mₓ. By design, both the parallel and anti-parallel configurations remain stable in the quiescent state and/or during a read operation (at sufficiently low read current).

In an embodiment, selector element Sₓ is an ovonic threshold switch that includes a first region 236 and optionally includes a second region 238 disposed above first region 236. In an embodiment, first region 236 is a SiTe alloy, and optional second region 238 is carbon nitride. Other materials may be used for first region 236 and optional second region 238. In other embodiments, selector element Sₓ is a conductive bridge threshold selector element. In an embodiment, first region 236 is a solid electrolyte region, and second region 238 is an ion source region.

FIG. 2C is a diagram depicting example current-voltage (I-V) characteristics of a threshold selector device Sₓ. Each threshold selector device Sₓ is initially in a high resistance (OFF) state. To operate threshold selector device Sₓ as a threshold switch, an initial forming operation may be necessary so that threshold selector device Sₓ operates in a current range in which switching can occur.

For example, a forming operation may include applying to threshold selector device Sₓ one or more voltage pulses each having a magnitude greater than or equal to a forming voltage V_{FORM}. Following the forming operation, threshold selector device Sₓ may be switched ON and OFF, and may be used as either a unipolar or a bipolar threshold selector device. Accordingly, threshold selector device Sₓ may be referred to as a bipolar threshold selector device.

In the example I-V characteristics of FIG. 2C, for positive applied voltages, threshold selector device Sₓ remains in a high resistance state (HRS) (e.g., OFF) until the voltage across the device meets or exceeds (i.e., is more positive than) a first threshold voltage, V_{TP}, at which point threshold selector device Sₓ switches to a low resistance state (LRS) (e.g., ON). Threshold selector device Sₓ remains turned ON until the voltage across the device drops to or below a first hold voltage, VHP, at which point threshold selector device 224 turns OFF.

For negative applied voltages, threshold selector device Sₓ remains in a HRS (e.g., OFF) until the voltage across the device meets or exceeds (i.e., is more negative than) a second threshold voltage, V_{TN}, at which point threshold selector device 304 switches to a LRS (e.g., ON). Threshold selector device Sₓ remains turned ON until the voltage across the device increases to or exceeds (i.e., is less negative than) a second hold voltage, V_{HN}, at which point threshold selector device Sₓ turns OFF.

Referring again to FIG. 2B, in an embodiment, magnetic memory element Mₓ uses spin-transfer-torque (STT) switching. To “set” a bit value of magnetic memory element Mₓ (i.e., choose the direction of the free layer magnetization), an electrical write current is applied from first terminal T1 to second terminal T2. The electrons in the write current become spin-polarized as they pass through pinned layer 230 because pinned layer 230 is a ferromagnetic metal.

A substantial majority of the conduction electrons in a ferromagnet will have a spin orientation that is parallel to the direction of magnetization, yielding a net spin polarized current. (Electron spin refers to angular momentum, which is directly proportional to but anti-parallel in direction to the magnetic moment of the electron, but this directional distinction will not be used going forward for ease of discussion.)

When the spin-polarized electrons tunnel across TB 234, conservation of angular momentum can result in the imparting of a torque on both free layer 232 and pinned layer 230, but this torque is inadequate (by design) to affect the direction of magnetization of pinned layer 230. Contrastingly, this torque is (by design) sufficient to switch the direction of magnetization of free layer 232 to become parallel to that of pinned layer 230 if the initial direction of magnetization of free layer 232 was anti-parallel to pinned layer 230. The parallel magnetizations will then remain stable before and after such write current is turned OFF.

In contrast, if free layer 232 and pinned layer 230 magnetizations are initially parallel, the direction of magnetization of free layer 232 can be STT-switched to become anti-parallel to that of pinned layer 230 by applying a write current of opposite direction to the aforementioned case. Thus, by way of the same STT physics, the direction of the magnetization of free-layer 232 can be deterministically set into either of two stable orientations by judicious choice of the write current direction (polarity).

In the example described above, spin-transfer-torque (STT) switching is used to “set” a bit value of magnetic memory element Mₓ. In other embodiments, field-induced switching, spin orbit torque (SOT) switching, VCMA (magnetoelectric) switching, or other switching techniques may be employed.

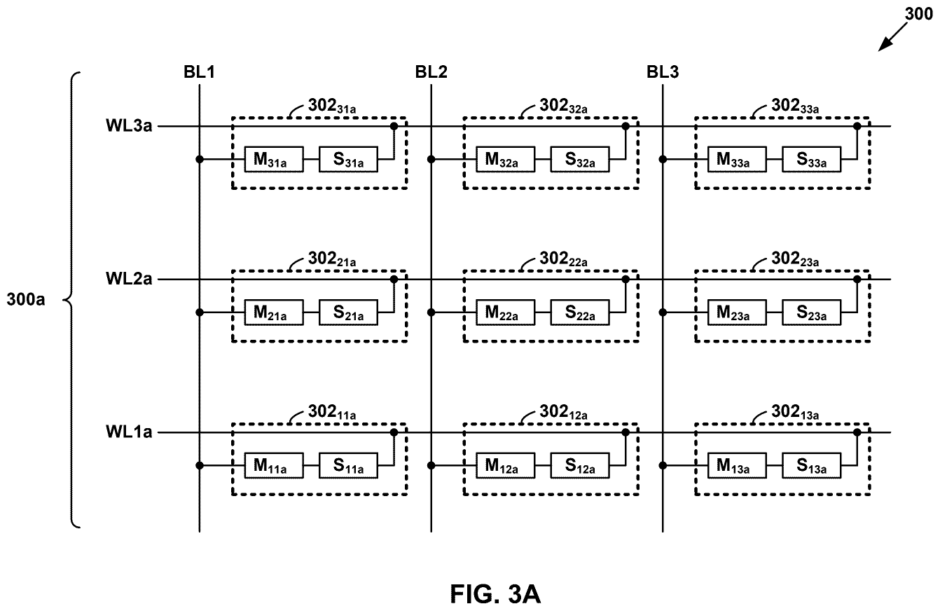

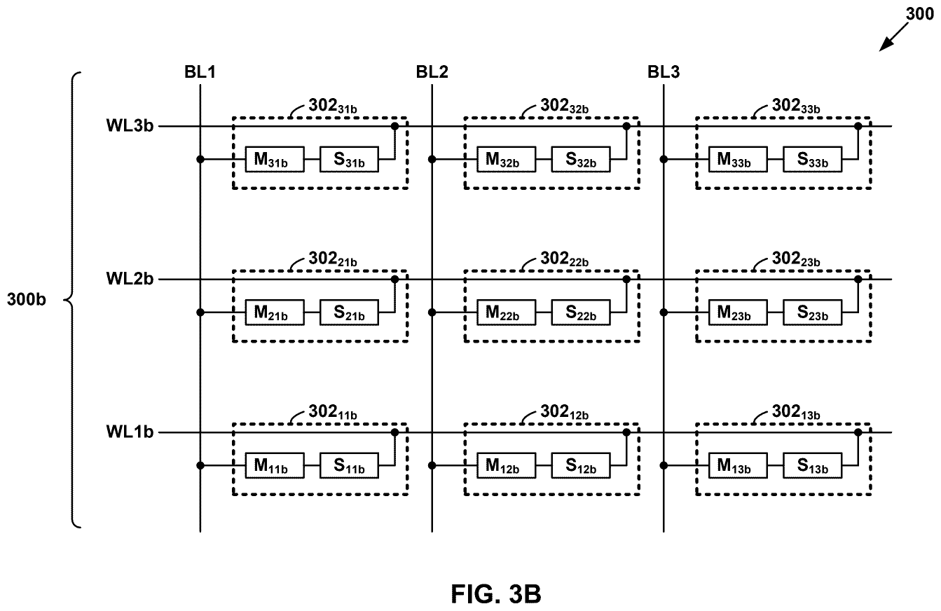

FIGS. 3A-3B are simplified schematic diagrams of an example cross-point memory array 300 which includes a first memory level 300a, and a second memory level 300b positioned above first memory level 300a. Cross-point memory array 300 is an example of an implementation of memory array 160 in FIG. 1E. Cross-point memory array 300 may include more than two memory levels.

Cross-point memory array 300 includes word lines WL1a, WL2a, WL3a, WL1b, WL2b, and WL3b, and bit lines BL1, BL2, and BL3. First memory level 300a includes memory cells 302₁₁ₐ, 302₁₂ₐ, . . . , 302₃₃ₐ coupled to word lines WL1a, WL2a, WL3a and bit lines BL1, BL2, and BL3, and second memory level 300b includes memory cells 302_{11b}, 302_{12b}, . . . , 302_{33b} coupled to word lines WL1b, WL2b, WL3b and bit lines BL1, BL2, and BL3. In an embodiment, each of memory cells 302₁₁ₐ, 302₁₂ₐ, . . . , 302₃₃ₐ are vertically-oriented. In an embodiment, each of memory cells 302_{11b}, 302_{12b}, . . . , 302_{33b} are vertically-oriented.

First memory level 300a is one example of an implementation for first memory level 212 of monolithic three-dimensional memory array 210 of FIG. 2A, and second memory level 300b is one example of an implementation for second memory level 214 of monolithic three-dimensional memory array 210 of FIG. 2A. In an embodiment, each of memory cells 202₁₁ₐ, 302₁₂ₐ, . . . , 302₃₃ₐ, 302_{11b}, 302_{12b}, . . . , 302_{33b}, is an implementation of memory cell 222a of FIG. 2B.

Persons of ordinary skill in the art will understand that cross-point memory array 300 may include more or less than six word lines, more or less than three bit lines, and more or less than eighteen memory cells 302₁₁ₐ, 302₁₂ₐ, . . . , 302₃₃ₐ, 302_{11b}, 302_{12b}, . . . , 302_{33b}. In some embodiments, cross-point memory array 300 may include 1000×1000 memory cells, although other array sizes may be used.

Each memory cell 302₁₁ₐ, 302₁₂ₐ, . . . , 302₃₃ₐ, 302_{11b}, 302_{12b}, . . . , 302_{33b} is coupled to one of the word lines and one of the bit lines, and includes a corresponding magnetic memory element M₁₁ₐ, M₁₂ₐ, . . . , M₃₃ₐ, M_{11b}, M_{12b}, . . . , M_{33b}, respectively, coupled in series with a corresponding selector element S₁₁ₐ, S₁₂ₐ, . . . , S₃₃ₐ, S_{11b}, S_{12b}, . . . , S_{33b}, respectively. In an embodiment, each of magnetic memory elements M₁₁ₐ, M₁₂ₐ, . . . , M₃₃ₐ, M_{11b}, M_{12b}, . . . , M_{33b} is an implementation of magnetic memory element Mₓ of FIG. 2B, and each of selector elements S₁₁ₐ, S₁₂ₐ, . . . , S₃₃ₐ, S_{11b}, S_{12b}, . . . , S_{33b} is an implementation of selector element Sₓ of FIG. 2B.

Each memory cell 302₁₁ₐ, 302₁₂ₐ, . . . , 302₃₃ₐ has a first terminal coupled to one of bit lines BL1, BL2, BL3, and a second terminal coupled to one of word lines WL1a, WL2a, WL3a, and each memory cell 302_{11b}, 302_{12b}, . . . , 302_{33b} has a first terminal coupled to one of bit lines BL1, BL2, BL3, and a second terminal coupled to one of word lines WL1b, WL2b, WL3b. For example, memory cell 302₁₃ₐ includes magnetic memory element M₁₃ₐ coupled in series with selector element S₁₃ₐ, and includes a first terminal coupled to bit line BL3, and a second terminal coupled to word line WL1a.

Likewise, memory cell 302_{22b} includes magnetic memory element M_{22b} coupled in series with selector element S22b, and includes a first terminal coupled to bit line BL2, and a second terminal coupled to word line WL2b. Similarly, memory cell 302₃₃ₐ includes magnetic memory element M₃₃ₐ coupled in series with selector element S₃₃ₐ, and includes a first terminal coupled to bit line BL3, and a second terminal coupled to word line WL3a.

Magnetic memory elements M₁₁ₐ, M₁₂ₐ, . . . , M₃₃ₐ may be disposed above or below corresponding selector elements S₁₁ₐ, S₁₂ₐ, . . . , S₃₃ₐ, respectively, and magnetic memory elements M_{11b}, M_{12b}, . . . , M_{33b}, may be disposed above or below corresponding selector elements S_{11b}, S_{12b}, . . . , S_{33b}, respectively.

In an embodiment, the orientation of memory cells 302₁₁ₐ, 302₁₂ₐ, . . . , 302₃₃ₐ of first memory level 300a is the same as the orientation of memory cell 302_{11b}, 302_{12b}, . . . , 302_{33b} of second memory level 300b.

In another embodiment, the orientation of memory cells 302₁₁ₐ, 302₁₂ₐ, . . . , 302₃₃ₐ of first memory level 300a is opposite the orientation of memory cell 302_{11b}, 302_{12b}, . . . , 302_{33b} of second memory level 300b.

As described above, in an embodiment each of memory cells 302₁₁ₐ, 302₁₂ₐ, . . . , 302₃₃ₐ, 302_{11b}, 302_{12b}, . . . , 302_{33b} of example cross-point memory array 300 of FIGS. 3A-3B is an implementation of memory cell 222a of FIG. 2B. In an embodiment, each of memory cells 302₁₁ₐ, 302₁₂ₐ, . . . , 302₃₃ₐ, 302_{11b}, 302_{12b}, . . . , 302_{33b} includes a corresponding magnetic memory element M₁₁ₐ, M₁₂ₐ, . . . , M₃₃ₐ, M_{11b}, M_{12b}, . . . , M_{33b}, respectively, coupled in series with a corresponding selector element S₁₁ₐ, S₁₂ₐ, . . . , S₃₃ₐ, S_{11b}, S_{12b}, . . . , S_{33b}, respectively.

As described above, in embodiments a magnetic memory element M_{X} may be switched between a relatively low resistance P state, and a relatively high resistance AP state. In embodiments, the data state (“0” or “1”) of a magnetic memory element Mₓ is read by measuring the resistance of magnetic memory element Mₓ using a relatively low read current.

For example, a magnetic memory element M_{X} may be switched between a P state resistance of approximately 40 kΩ and an AP state resistance of approximately 60 kΩ. During a read operation, a relatively small current (e.g., approximately 10 μA) is conducted through the cell to detect a difference in voltage drops across the magnetic memory element M_{X} via Ohm's Law:

$$Vcell ( AP ) = 10 μA \times 60 k Ω = 600 mV \qquad ( 1 a )$$

$$Vcell ( P ) = 10 μA \times 40 k Ω = 400 mV \qquad ( 1 b )$$

Thus, ignoring any voltage drop across the selector element S_{X}, in this example there is a 200 mV difference in the voltage across the memory cell 33_{XX} when the memory element M_{X} is switched between the P state and AP state.

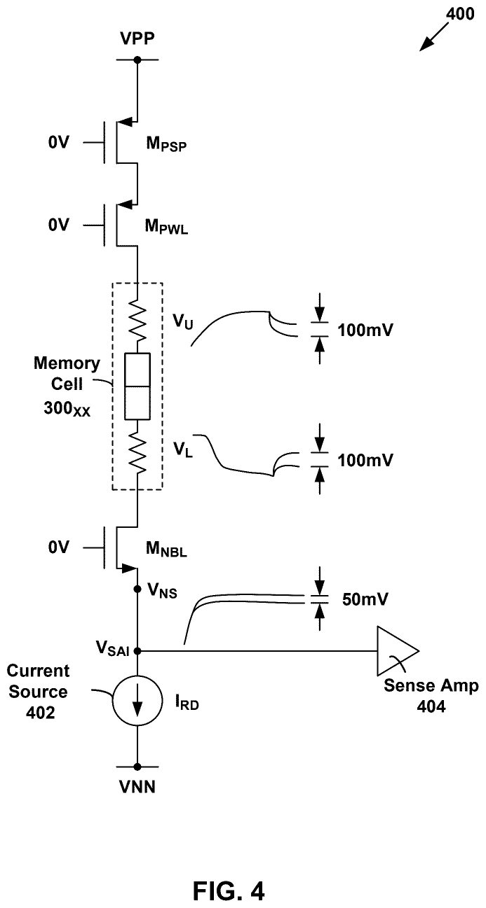

FIG. 4 is a simplified diagram of an example memory circuit 400 during a read operation of a memory cell 300_{XX}. In an embodiment, memory cell 300_{XX} is an implementation of memory cell 222a of FIG. 2B. Disposed above memory cell 300_{XX} is a p-channel transistor M_{PWL} representing transistors in a word line driver, and a p-channel transistor M_{PSP} representing a switch to a first power supply voltage VPP (e.g., +3V). In an embodiment, gate terminals of p-channel transistors M_{PWL} and M_{PSP} are coupled to bias voltage (e.g., 0V or some other voltage).

In an embodiment, disposed below memory cell 300_{XX} is an n-channel transistor M_{NBL} representing transistors in a bit line line driver, which is coupled via a current source 402 (e.g., an n-channel current mirror transistor) to a second power supply voltage VNN (e.g., −3V). In an embodiment, gate terminals of p-channel transistors M_{PWL} and M_{PSP} are coupled to bias voltage (e.g., 0V or some other voltage). In an embodiment, a source terminal V_{NS} of n-channel transistor M_{NBL} is coupled to an input terminal V_{SAI} of a sense amplifier circuit 404.

In an embodiment, during a read operation current source 402 conducts a read current I_{RD}, which is conducted by each of p-channel transistors M_{PWL} and M_{PSP}, memory cell 300_{XX}, and n-channel transistor M_{NBL}. The resistors depicted in memory cell 300_{XX} represent the resistance of magnetic memory element M_{X} of memory cell 300_{XX}. In an embodiment, read current I_{RD} has a value of about 10 μA, or some other value.

As described above, in an embodiment magnetic memory element M_{X} may be switched between a P state resistance of approximately 40 kΩ and an AP state resistance of approximately 60 kΩ. As described above, in this example there is a 200 mV difference in the voltage across memory cell 300_{XX} when the memory element M_{X} is switched between the P state and AP state.

As depicted in FIG. 4, the 200 mV voltage difference is divided approximately evenly between the upper and lower halves of memory circuit 400. In particular, voltages along the path adjust to support a larger AP resistance. In embodiments, voltages above memory cell 300_{XX} move up, and voltages below memory cell 300_{XX} move down relative to the P state.

In an embodiment, this action provides the required PMOS/NMOS VGS/VDS adjustments to support the additional IR drop in the path. Consequently, approximately half of the signal (e.g., 100 mV) is lost as it propagates upward, and approximately the other half of the signal (e.g., 100 mV) propagates down toward sense amplifier circuit 404.

The 100 mV voltage difference is further attenuated as it travels from the middle of the memory array down to sense amplifier circuit 404, such that at the source terminal V_{NS} of n-channel transistor M_{NBL} (which is also the input terminal V_{SAI} of a sense amplifier circuit 404) the voltage difference at the input terminal of sense amplifier circuit 404 reduces to approximately 50 mV.

In an embodiment, sense amplifier circuit 404 is configured to compare the signal at input terminal V_{SAI} (which is based on a voltage across memory cell 300_{XX}) with a reference voltage to determine if magnetic memory element M_{X} is in P state resistance or AP state resistance. However, distinguishing such a small voltage difference between the two states is very difficult to accurately sense by an actual sense amplifier circuit 404, which may have randomized circuit mismatches resulting in tens of millivolts of input voltage offsets. Indeed, the smaller the signal difference at input terminal V_{SAI}, the less likely that sense amplifier circuit 404 will generate a correct output.

One solution to this problem would be to increase read current I_{RD} to increase the memory cell voltage difference between the P state and AP state. However, increasing read current I_{RD} risks inadvertently changing the state of memory element M_{X} in memory cell 300_{XX}.

Technology is described to amplify the signal at input terminal V_{SAI} of a sense amplifier circuit 404. In an embodiment, an amplifier circuit is disposed between source terminal V_{NS} of n-channel transistor M_{NBL} and input terminal V_{SAI} of a sense amplifier circuit 404. In an embodiment, the amplifier circuit is configured to amplify a voltage at the input terminal V_{SAI} of a sense amplifier circuit 404, which voltage is based on a voltage across memory cell 300_{XX}. In an embodiment, the amplifier circuit is a common-gate amplifier circuit. In an embodiment, the amplifier circuit is a p-channel transistor configured as a common-gate amplifier circuit.

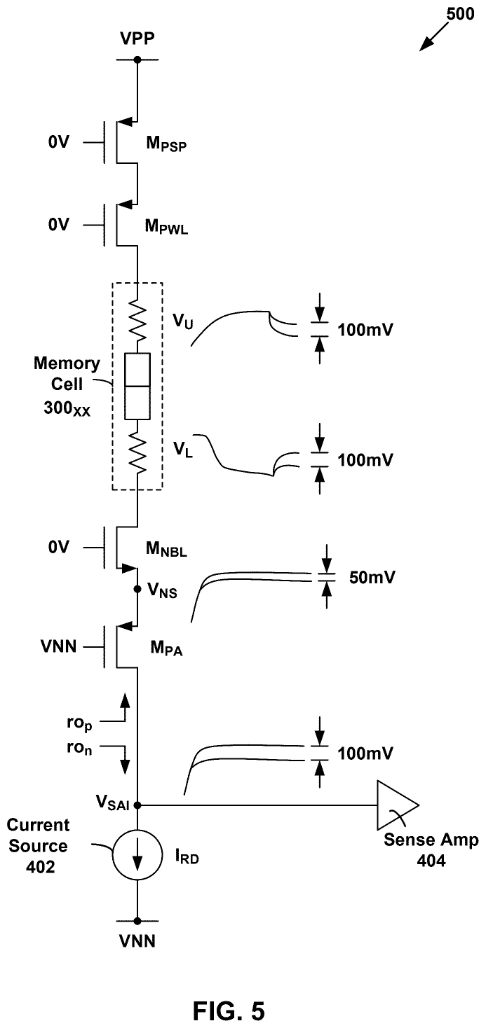

FIG. 5 is a simplified diagram of another example memory circuit 500 during a read operation of a memory cell 300_{XX}. Example memory circuit 500 is similar to memory circuit 400 of FIG. 4, but also includes a p-channel transistor M_{PA} disposed between source terminal V_{NS} of n-channel transistor M_{NBL} and input terminal V_{SAI} of a sense amplifier circuit 404.

In an embodiment, a p-channel transistor M_{PA} is configured as a “common gate” amplifier. In an embodiment, p-channel transistor M_{PA} has a first terminal (e.g., a drain terminal or output terminal) coupled to current source 402 and input terminal V_{SAI} of a sense amplifier circuit 404, a second terminal (e.g., a gate terminal) coupled to a DC bias (e.g., second power supply voltage VNN), and a third terminal (e.g., a source terminal or input terminal) coupled to source terminal V_{NS} of n-channel transistor M_{NBL}.

In an embodiment, current source 402 is implemented as a saturated n-channel current mirror transistor that is configured to operate in a saturation region of operation and that conducts a drain current ID. In an embodiment, p-channel transistor M_{PA} also is configured to operate in a saturation region of operation. As a result, n-channel current mirror current source 402 has a relatively high output impedance rₒₙ, and p-channel transistor M_{PA} has a relatively high output impedance rₒₚ. In such a configuration, any difference in voltage at the input (source) terminal of p-channel transistor M_{PA} will result in a larger difference in voltage at the output (drain) terminal of p-channel transistor M_{PA}.

Thus, the signal at the output (drain) terminal of p-channel transistor M_{PA} (e.g., the signal at input terminal V_{SAI} of a sense amplifier circuit 404) is an amplified version of the signal at the input (source) terminal of p-channel transistor M_{PA} (e.g., the signal at the source terminal V_{NS} of n-channel transistor M_{NBL}):

$${V}_{SAI} = A \times {V}_{NS} \qquad ( 2 )$$

where A is the amplification factor, which is proportional to the parallel resistance of n-channel current mirror current source 402 output impedance rₒₙ and p-channel transistor M_{PA} output impedance rₒₚ. In an embodiment, amplification factor A may be about 2, or some other value.

From FIG. 4, the signal at the source terminal V_{NS} of n-channel transistor M_{NBL} had a voltage difference of about 50 mV. Thus, as depicted in FIG. 5, with an amplification factor A of about 2, the signal at input terminal V_{SAI} of a sense amplifier circuit 404 (which is based on the voltage across memory cell 300_{XX}) has a voltage difference of about 100 mV, which is in a desired range.

Referring again to FIG. 5, p-channel transistor M_{PA} provides an additional benefit to memory circuit 500. In particular, as described above in an embodiment memory cell 300_{XX} is an implementation of memory cell 222a of FIG. 2B, which includes a magnetic memory element Mₓ coupled in series with a selector element Sₓ. When a selector element Sₓ turns ON (e.g., transitions from a high resistance state to a low resistance state) capacitive discharge currents (referred to herein as “snapback”) may result, and in some instance may disturb the data state of the memory cell. In addition, snapback can negatively impact the endurance of the memory cell.

In an embodiment, memory cell 300_{XX} includes a first terminal coupled to a word line and a second terminal coupled to a bit line. One technique to reduce the magnitude of the capacitive discharge currents is to limit a lower (e.g., most negative) voltage on the bit line coupled to memory cell 300_{XX}. In an embodiment, p-channel transistor M_{PA} acts as a voltage regulator that limits how low the voltage at source terminal V_{NS} of p-channel transistor M_{PA} can go, and therefore limits a lower (e.g., most negative) voltage on the bit line coupled to memory cell 300_{XX}.

In particular, p-channel transistor M_{PA} is also configured as a source follower transistor. By coupling the gate of p-channel transistor M_{PA} to VNN, the voltage at source terminal V_{NS} of p-channel transistor M_{PA} is limited to one threshold voltage above VNN. This limits how low source terminal V_{NS} of p-channel transistor M_{PA} can go, which in turns limits the voltage on the bit line coupled to memory cell 300_{XX} and limits the current spike that occurs when selector element Sₓ turns ON.

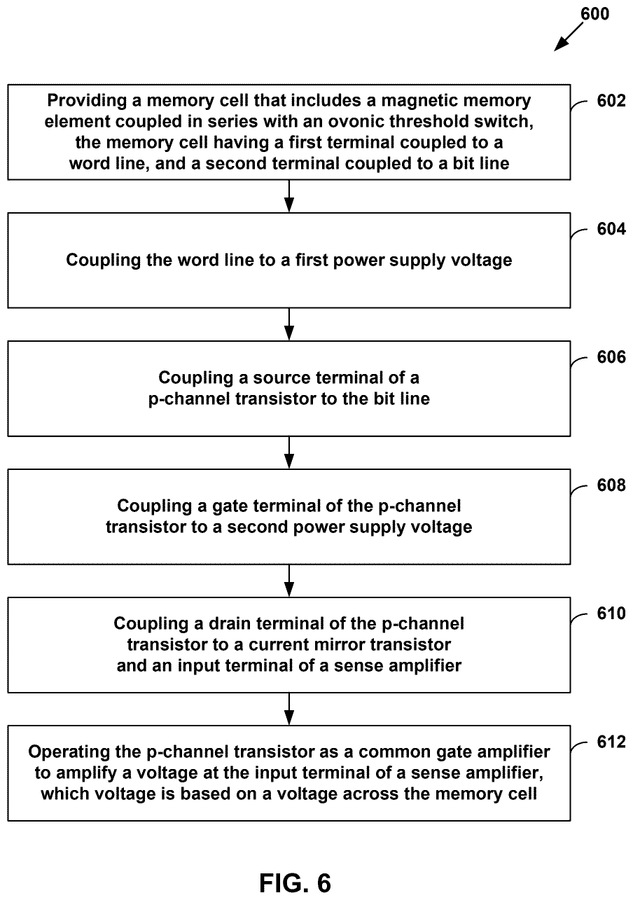

FIG. 6 depicts a flow diagram of an embodiment of a method 600 for configuring a memory cell, such as memory cell 222a of FIG. 2B.

At step 602, providing a memory cell that includes a magnetic memory element coupled in series with an ovonic threshold switch, the memory cell having a first terminal coupled to a word line, and a second terminal coupled to a bit line.

At step 604, coupling the word line to a first power supply voltage.

At step 606, coupling a source terminal of a p-channel transistor to the bit line.

At step 608, coupling a gate terminal of the p-channel transistor to a second power supply voltage.

At step 610, coupling a drain terminal of the p-channel transistor to a current mirror transistor and an input terminal of a sense amplifier.

At step 612, operating the p-channel transistor as a common gate amplifier to amplify a voltage at the input terminal of a sense amplifier, which voltage is based on a voltage across the memory cell.

One embodiment of the disclosed technology includes an apparatus that includes a memory cell including a magnetic memory element coupled in series with a selector element, the memory cell including a first terminal coupled to a word line driver circuit and a second terminal coupled to a bit line driver circuit, and an amplifier circuit comprising an input terminal coupled to the bit line driver circuit, and an output terminal coupled to a current source configured to conduct a read current. The amplifier circuit is configured to amplify a voltage that is based on a voltage across the memory cell.

One embodiment of the disclosed technology includes an apparatus that includes a memory cell including a magnetic memory element coupled in series with an ovonic threshold switch, the memory cell including a first terminal coupled to a word line, and a second coupled to a bit line, and a voltage regulator circuit including an output terminal coupled to the bit line, and an input terminal coupled to a second power supply voltage, the voltage regulator circuit configured to provide a lower limit on a voltage of the bit line. The voltage regulator circuit amplifies a difference between a first voltage across the memory cell and a second voltage across the memory cell.

One embodiment of the disclosed technology includes a method that includes providing a memory cell that includes a magnetic memory element coupled in series with an ovonic threshold switch, the memory cell having a first terminal coupled to a word line, and a second terminal coupled to a bit line, coupling the word line to a first power supply voltage, coupling a source terminal of a p-channel transistor to the bit line, coupling a gate terminal of the p-channel transistor to a second power supply voltage, coupling a drain terminal of the p-channel transistor to a current mirror transistor and an input terminal of a sense amplifier, and operating the p-channel transistor as a common gate amplifier to amplify a voltage at the input terminal of a sense amplifier, which voltage is based on a voltage across the memory cell.

For purposes of this document, a first layer may be over or above a second layer if zero, one, or more intervening layers are between the first layer and the second layer.

For purposes of this document, it should be noted that the dimensions of the various features depicted in the figures may not necessarily be drawn to scale.

For purposes of this document, reference in the specification to “an embodiment,” “one embodiment,” “some embodiments,” or “another embodiment” may be used to describe different embodiments and do not necessarily refer to the same embodiment.

For purposes of this document, a connection may be a direct connection or an indirect connection (e.g., via another part). In some cases, when an element is referred to as being connected or coupled to another element, the element may be directly connected to the other element or indirectly connected to the other element via intervening elements. When an element is referred to as being directly connected to another element, then there are no intervening elements between the element and the other element.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. An apparatus comprising:
a memory cell comprising a magnetic memory element coupled in series with a selector element, the memory cell comprising a first terminal coupled to a word line driver circuit and a second terminal coupled to a bit line driver circuit; and
an amplifier circuit comprising an input terminal coupled to the bit line driver circuit, and an output terminal coupled to a current source configured to conduct a read current,
wherein the amplifier circuit is configured to amplify a voltage that is based on a voltage across the memory cell.

2. The apparatus of claim 1, wherein the amplifier circuit comprises a common gate amplifier.

3. The apparatus of claim 1, wherein the amplifier circuit comprises a transistor comprising a first terminal coupled to the output terminal of the amplifier circuit, a second terminal coupled to the input terminal of the amplifier circuit, and a third terminal coupled to a power supply voltage.

4. The apparatus of claim 1, wherein the amplifier circuit comprises a transistor comprising a drain terminal comprising the output terminal of the amplifier circuit, a source terminal comprising the input terminal of the amplifier circuit, and a gate terminal coupled to a power supply voltage.

5. The apparatus of claim 1, wherein the amplifier circuit comprises a p-channel transistor configured to operate in a saturation region of operation.

6. The apparatus of claim 1, wherein the current source comprises a current mirror.

7. The apparatus of claim 1, further comprising a sense amplifier circuit comprising an input terminal coupled to the output terminal of the amplifier circuit.

8. The apparatus of claim 7, wherein the sense amplifier circuit is configured to compare a signal at the input terminal of the sense amplifier circuit with a reference voltage to determine a memory state of the memory cell.

9. The apparatus of claim 1, wherein the magnetic memory element is configured to switch between a first resistance state and a second resistance state.

10. The apparatus of claim 1, wherein:
the magnetic memory element conducts the read current;
the first voltage comprises a voltage drop across the magnetic memory element in a first resistance state; and
the second voltage comprises a voltage drop across the magnetic memory element in a second resistance state.

11. The apparatus of claim 1, wherein the selector element comprises an ovonic threshold switch.

12. The apparatus of claim 1, further comprising a cross-point memory array comprising the memory cell.

13. An apparatus comprising:
a memory cell comprising a magnetic memory element coupled in series with an ovonic threshold switch, the memory cell comprising a first terminal coupled to a word line, and a second coupled to a bit line; and
a voltage regulator circuit comprising an output terminal coupled to the bit line, and an input terminal coupled to a second power supply voltage, the voltage regulator circuit configured to provide a lower limit on a voltage of the bit line,
wherein voltage regulator circuit amplifies a voltage that is based on a voltage across the memory cell.

14. The apparatus of claim 13, wherein the voltage regulator circuit comprises a source follower transistor.

15. The apparatus of claim 13, wherein the voltage regulator circuit comprises a common gate amplifier.

16. The apparatus of claim 13, wherein the voltage regulator circuit comprises a p-channel transistor configured to operate in a saturation region of operation.

17. The apparatus of claim 1, further comprising a sense amplifier circuit comprising an input terminal coupled to a third terminal of the voltage regulator circuit.

18. The apparatus of claim 17, wherein the sense amplifier circuit is configured to compare a signal at the input terminal of the sense amplifier circuit with a reference voltage to determine a memory state of the memory cell.

19. The apparatus of claim 13, wherein the magnetic memory element is configured to switch between a first resistance state and a second resistance state.

20. A method comprising:
providing a memory cell comprising a magnetic memory element coupled in series with an ovonic threshold switch, the memory cell comprising a first terminal coupled to a word line, and a second terminal coupled to a bit line;
coupling the word line to a first power supply voltage;
coupling a source terminal of a p-channel transistor to the bit line;
coupling a gate terminal of the p-channel transistor to a second power supply voltage;
coupling a drain terminal of the p-channel transistor to a current mirror transistor and an input terminal of a sense amplifier; and
operating the p-channel transistor as a common gate amplifier to amplify a voltage at the input terminal of a sense amplifier, which voltage is based on a voltage across the memory cell.
